(19) United States
(12) Patent Application Publication
(10) Pub. No.: US 2025/0130298 A1
(43) Pub. Date: Apr. 24, 2025

(54) DEVICE FOR ANALYZING A LIQUID OR PASTY SAMPLE, WHICH IS PROVIDED IN THE FORM OF DROPS, USING NUCLEAR MAGNETIC RESONANCES OF THE SAMPLE

(71) Applicant: Analytik Jena GmbH+Co. KG, Jena (DE)

(72) Inventors: Thomas Moore, Jena-Drackendorf (DE); Daniel Weigel, Jena (DE); Mohammad Sadegh Ebrahimi, Lörrach (DE)

(21) Appl. No.: 18/683,066

(22) PCT Filed: Jul. 22, 2022
(86) PCT No.: PCT/EP2022/070603

§ 371 Date: Feb. 12, 2024

(30) Foreign Application Priority Data
Aug. 11, 2021 (DE) 10 2021 120 972.2

(51) Int. Cl. G01R 33/30; G01N 24/00; G01N 24/08

(52) U.S. Cl. CPC G01R 33/302; G01N 24/006; G01N 24/08

(57) ABSTRACT

A device for analyzing a liquid or pasty sample, which is provided in the form of drops, using nuclear spin resonances of the sample includes: a first plate and a second plate; a mechanism via which a measuring position and a recording position can be set, wherein the first plate and the second plate are arranged substantially parallel to each other in the measuring position, wherein a spacer sets a defined spacing between the first plate and the second plate; a sensor unit with a sensor component, which forms at least one sub-region of the first plate and/or the second plate and at least partly contacts the sample, wherein the sensor unit is designed to detect a variable which is influenced by the nuclear magnetic resonances of the sample; and an analysis unit.

The invention relates to a device for analyzing a liquid or pasty sample, which is provided in the form of drops, using nuclear spin resonances of the sample.

Nuclear magnetic resonance spectroscopy (NMR spectroscopy) allows the investigation of the electronic environment of individual atoms and their interactions with the neighboring atoms. By means of NMR spectroscopy, components of samples and the structures of molecules can be determined. NMR spectroscopy also forms the basis of magnetic resonance tomography, which is frequently used in the medical or biological sector for examining tissues and organs.

Many atomic nuclei have a nuclear spin different from zero and, therefore, a magnetic moment as rotating charge carriers, such as, e.g., ¹H or ¹³C atoms. In a static magnetic field, nuclear spins result in a precessing movement, the so-called Larmor precession, about the axis of the constant magnetic field. In this case, the atomic nuclei change the orientation of their nuclear spins relative to the magnetic field by absorption or emission of alternating magnetic fields if they are resonant with the Larmor frequency. This is also known as nuclear magnetic resonance. The possible magnetic rotary pulse quantum states of the nuclear spins are equidistant and dependent on the Larmor frequency. The frequency and the duration of the Larmor precession are dependent on the respective nuclear spin along with its spatial and chemical environment. The detection of the Larmor precessions on the basis of the Larmor frequencies therefore enables a very precise determination of the chemical composition of the sample and the spatial structure of the molecules contained in the sample.

The alternating magnetic field is generally generated by a magnetic coil. In conventional NMR spectroscopy, inductive methods for detecting nuclear magnetic resonances are frequently used. The sample is accordingly often surrounded by an induction coil, in which an electrical voltage is generated by the magnetic alternating fields emitted by the precessing nuclear spins. Typically, strong static magnetic fields of up to 25 T are used for polarization of the nuclear spins in order to obtain a preferred polarization of identically oriented nuclear spins and therefore a magnetization that can be measured using conventional magnetic field sensors. A miniaturization of the NMR measuring devices is therefore generally not possible. The sample to be investigated is generally introduced into long glass tubes. The required sample volume lies at a few milliliters. However, in particular in the life science sector, this is a major disadvantage, since the available volumes of the samples are often in the microliter range. For example, frequently only a few microliters of sample can be extracted from cell cultures or tissue points.

A newer generation of magnetic field sensors falls under the rubric of so-called quantum sensors with which a wide variety of quantum effects are used to determine various physical and/or chemical measured variables. In the field of industrial process automation, such approaches are of interest in particular with regard to increasing efforts towards miniaturization, while at the same time increasing the performance of the respective sensors.

Quantum sensors are based upon the fact that certain quantum states of individual atoms can be controlled and read very precisely. In this way, for example, precise and low-interference measurements of electrical and/or magnetic fields as well as gravitational fields with resolutions in the nanometer range are possible. In this context, various spin-based sensor assemblies have become known, for which atomic transitions in crystal bodies are used for detecting changes of movements, electrical and/or magnetic fields or also gravitational fields. Furthermore, different systems based on quantum-optic effects have also become known, such as, for example, quantum-gravimeters or optically pumped magnetometers, wherein in particular the latter are based, inter alia, on gas cells.

For example, in the field of spin-based quantum sensors, various devices have become known that utilize atomic transitions, for example, in various crystal bodies, in order to detect even small changes in movements, electric and/or magnetic fields or even gravitational fields. Typically, diamond with at least one silicon or nitrogen defect center, silicon carbide with at least one silicon defect, or hexagonal boron nitride with at least one defect color center is used as crystal body. The crystal bodies can in principle have one or more vacancies.

Another sub-area in the field of quantum sensors relates to gas cells in which atomic transitions and spin states can be optically queried, among other things, to determine magnetic and/or electrical properties. In general, a gaseous alkali metal and a buffer gas are present in the gas cell. Magnetic properties of a surrounding medium can be determined by Rydberg states generated in the gas cell. For example, gas cells are used in quantum-based standards which provide physical variables with high precision. They have therefore long been used in frequency standards or atomic clocks, as is known from EP 0 550 240 E1.

It is therefore the object of the present invention to specify a device by means of which the nuclear spin resonances of small sample volumes, for example, below 100 μl, can be detected in a simple manner.

The object is achieved according to the invention by a device for analyzing a liquid or pasty sample, which is provided in the form of drops, using nuclear spin resonances of the sample, comprising:
a first plate and a second plate,
a mechanism via which a measuring position and a recording position can be set, wherein the sample can be inserted between the first plate and the second plate in the recording position, wherein the first plate and the second plate are arranged substantially parallel to each other in the measuring position, and a spacer sets a defined spacing between the first plate and the second plate,
a sensor unit with a sensor component, which forms at least one sub-region of the first plate and/or the second plate and at least partly contacts the sample, wherein the sensor unit is designed to detect a variable which is influenced by the nuclear magnetic resonances of the sample,
an analysis unit, which ascertains at least one chemical and/or physical property of the sample using the detected variable.

In the device according to the invention, the sample is clamped between the first plate and the second plate. The sample is thereby kept static by the interfacial tension between the sample and the two plates and by the adhesion force of the sample to the two plates. With the aid of the spacer, a defined distance between the two plates and therefore a defined layer thickness of the sample is set, wherein the defined distance is set depending on the properties of the sample and the contact surface properties of the two plates. The properties of the sample and the surface condition of the two plates relate, in particular, to their hydrophobicity/hydrophilicity and lipophilicity/lipophobicity and, in the case of the surface condition, to the roughness of the surfaces of the two plates facing the sample.

In the receiving position of the device, the sample is applied, for example, to the first plate or the second plate by means of a pipette. By setting the measurement position and the associated parallel arrangement of the two plates, the sample introduced in the form of drops is flattened, and the contact surface of the sample with the first plate and the second plate therefore greatly increases. The defined distance between the first plate and the second plate is therefore generally set smaller than the height of the drop relative to the first plate and/or second plate. The device according to the invention can therefore be used with very low volumes of sample. By clamping the sample between the two plates, the evaporation of the sample is also greatly limited or avoided. Due to the increased contact surface between the sample and the first plate and between the sample and the second plate, the detection of the variable influenced by the nuclear magnetic resonances of the sample is facilitated. The variable influenced by the nuclear spin resonances of the sample is in particular an optical variable and, in particular, a variable dependent on the nuclear magnetic resonances. The first plate and/or the second plate are, for example, designed to be transparent as a plastic or glass if the sensor component forms a part of the first plate and/or the second plate. It is also possible for the sensor component to completely form the first plate and/or the second plate.

The mechanism for setting the measuring and receiving position can be configured such that the device can be designed in one part or in two parts. Given the possibility of setting the receiving position, the device cannot only be loaded with the sample, but can also be cleaned in a simple manner.

In one embodiment, the sensor component has at least one crystal body with at least one vacancy or at least one gas cell. The crystal body with at least one vacancy as well as gas cells exhibit, with corresponding optical excitation, a fluorescence signal, which is dependent, inter alia, on a magnetic field applied to the crystal body or the gas cell. The nuclear spin resonances of the sample influence the magnetic field applied to the sensor component, so that at least one chemical and/or physical property of the sample can be ascertained by means of the fluorescence signal. To this end, contact between the sample and the sensor component is necessary. The increased contact surface between the sample and the first plate and between the sample and the second plate increases the sensitivity of the device. Both the crystal body with the at least one vacancy center and the gas cell lead to an improvement in the measurement accuracy of the detection of nuclear magnetic resonances of the sample and therefore of the at least one chemical and/or physical property of the sample due to their high sensitivity to magnetic fields. In addition, information about the magnetic flux density, the magnetic susceptibility, the magnetic permeability or another variable related to at least one of these variables can be ascertained using the fluorescence signal.

In another embodiment, the crystal body is a diamond with at least one nitrogen vacancy center, silicon carbide with at least one silicon vacancy center or hexagonal boron nitride with at least one vacancy color center.

In another embodiment, the gas cell is a cell which includes at least one gaseous alkali metal.

The sensor unit preferably has an excitation unit for the optical excitation of the sensor component and a detection unit for the detection of a fluorescence signal of the sensor component influenced by the nuclear magnetic resonances of the sample. In addition, other optical elements such as filters, apertures and mirrors can optionally be used.

Advantageously, the excitation unit and/or the detection unit are arranged adjacent to the first plate and/or second plate such that an optical beam path through the sample can be generated. The first plate and the second plate have to be at least partially transparent to the excitation light and the fluorescent light. The sample is in particular arranged between the excitation unit and the detection unit. This arrangement has the advantage that the sensor component can be formed both as a sub-region of the first plate and as a sub-region of the second plate, so that a large contact surface between the sample and the sensor component, and therefore a high sensitivity of the device, is achieved. Alternatively, the excitation unit and the detection unit are arranged either in the region of the first plate or the second plate. In this case, a reflection layer can additionally be applied to the plate opposite the excitation and detection unit in order to reflect the variable influenced by the nuclear magnetic resonance to the detection unit.

In another embodiment, the detection unit is designed such that the detection unit detects the fluorescence signal of the crystal body or of the gas cell and does not detect the excitation light of the excitation unit. The detection unit substantially detects exclusively the fluorescence signal of the crystal body with at least one vacancy or the gas cell. The fluorescence signal usually comprises at least one wavelength, typically a plurality of wavelengths or a band at wavelengths.

In another embodiment, the detection unit is equipped with an absorption filter, wherein the absorption filter is arranged between the detection unit and the first plate or the second plate. The absorption filter serves to absorb the excitation light and possibly additional light from the surroundings, so that substantially only the fluorescence signal impinges on the detection unit.

In another embodiment, the mechanism is a folding mechanism, wherein the folding mechanism in particular comprises a hinge mechanism. By means of the folding mechanism, the device can be brought into the measuring and receiving position in a simple manner. In particular, no components of the device need to be disassembled; rather, a folding movement is sufficient for changing between the two positions.

An inductor is preferably provided which is designed to induce a preferred polarization of the nuclear spins of the sample. The inductor is in particular a magnetic field device which generates an, in particular static, magnetic field at least in a region of the sample and in the region of the sensor component. Instead of a magnetic field device, the inductor can be based on another method of hyperpolarization, i.e., for example, in the form of parahydrogen flowing through the sample. It is also possible to design the inductor as a laser source and/or microwave antenna and therefore induce a preferred polarization in the electron spins of the sensor component, and subsequently transmit this preferred polarization of the electron spins to the nuclear spins of the sample. In particular, the excitation unit can be used as a laser source. The microwave antenna can be used both for induction of a preferred polarization of the nuclear spins of the sample and for excitation of the sensor component.

Advantageously, the magnetic field device is arranged adjacent to the excitation unit and/or detection unit such that a homogeneous magnetic field can be generated in the region of the sample and in the region of the sensor component, wherein the magnetic field device is designed in particular as a yoke or in two parts.

In another embodiment, the sample has a volume of less than 100 μl, in particular less than 10 μl.

In another embodiment, the defined distance between the first plate and the second plate is between 1 mm and 100 μm.

In another embodiment, a microwave source is provided for exciting the sensor component.

In another embodiment, the sensor component is designed as a coating on a surface of the first plate and/or the second plate facing the sample. In the case of a crystal body having at least one vacancy, it can be applied to the first plate and/or the second plate using a CVD or PVD method, for example. The first plate and/or the second plate serve as a substrate and are made of glass, for example.

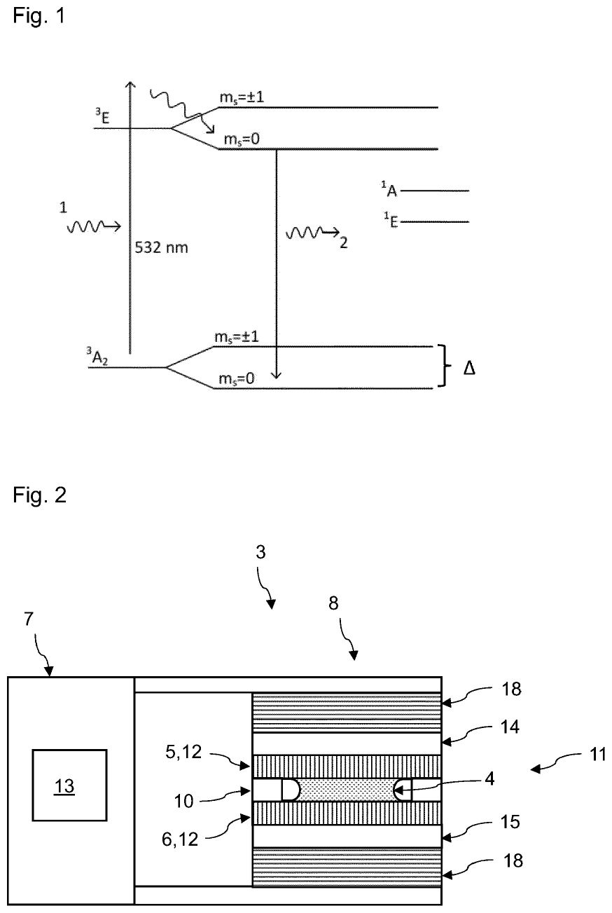

The invention is explained in more detail below with reference to FIGS. 1-4. Shown are:

FIG. 1: a simplified energy diagram for a negatively charged NV center in the diamond.

FIG. 2: a first embodiment of the device according to the invention.

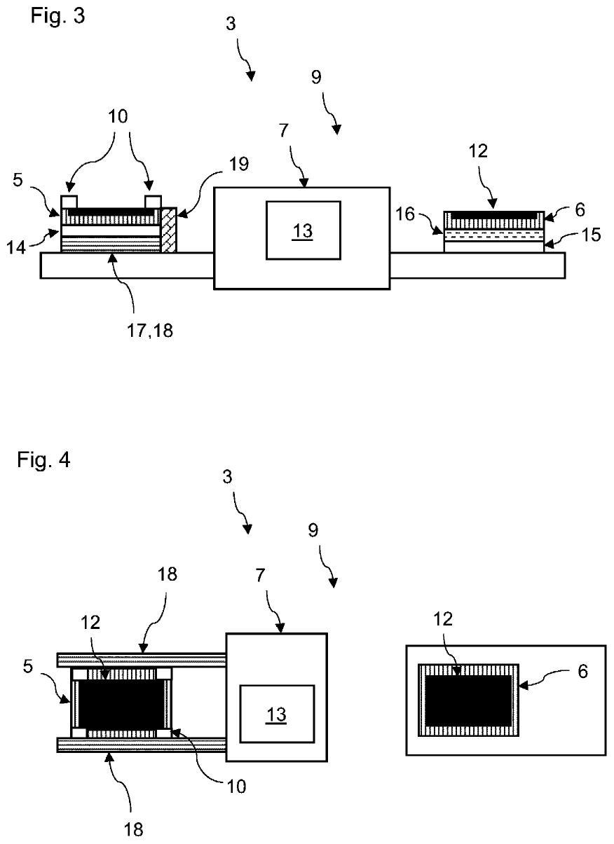

FIG. 3: a second embodiment of the device according to the invention.

FIG. 4: a third embodiment of the device according to the invention.

FIG. 1 shows a simplified energy diagram for a negatively charged nitrogen void center (NV center) in a diamond to exemplify the excitation and fluorescence of a vacancy in a crystal body. The following considerations can be transferred to other crystal bodies having corresponding vacancies.

In the diamond, each carbon atom is typically covalently bonded to four further carbon atoms. A nitrogen vacancy center (NV center) consists of a vacancy in the diamond lattice, i.e., an unoccupied lattice site, and a nitrogen atom as one of the four neighboring atoms. In particular, the negatively charged NV⁻ centers are important for the excitation and evaluation of fluorescence signals. In the energy diagram of a negatively charged NV center, there is a triplet ground state ³A and an excited triplet state ³E, each of which has three magnetic substates mₛ=0,±1. Furthermore, there are two metastable singlet states ¹A and ¹E between the ground state ³A and the excited state ³E. In the absence of an external magnetic field, a splitting of the two states mₛ=+/−1 from the ground state mₛ=0 occurs, which is referred to as zero-field splitting Δ and which is dependent upon the temperature T.

Excitation light 1 from the green range of the visible spectrum, e.g., an excitation light 1 with a wavelength of 532 nm, excites an electron from the ground state ³A into a vibrational state of the excited state ³E, which returns to the ground state ³A by emitting a fluorescence photon 2 with a wavelength of 630 nm. This fluorescence signal is a measure of the zero-field splitting Δ and can be used to determine and/or monitor the temperature T.

An applied magnetic field with a magnetic field strength B leads to a splitting (Zeeman splitting) of the magnetic sub-states, so that the ground state consists of three energetically separated sub-states, each of which can be excited. However, the intensity of the fluorescence signal is dependent on the respective magnetic substate from which it was excited, so that the magnetic field strength B, for example, can be calculated using the Zeeman formula on the basis of the distance between the fluorescence minima. The magnetic field strength B is modified by the nuclear spins of the sample 4 or results therefrom.

In the context of the present invention, further possibilities for evaluating the fluorescence signal are provided, such as the evaluation of the intensity of the fluorescent light, which is likewise proportional to the applied magnetic field. An electrical evaluation can in turn be done, for example, via a Photocurrent Detection of Magnetic Resonance (PDMR). In addition to these examples for evaluating the fluorescence signal, there are other possibilities which also fall within the scope of the present invention.

FIG. 2 shows a first embodiment of the device 3 according to the invention. A measurement position 8, in which the sample 4 is enclosed between the first plate 5 and the second plate 6, is set by means of the mechanism 7. The mechanism 7 can, for example, cause the device 3 to be unfolded or removed. In the measuring position 8, the first plate 5 and the second plate 6 are oriented substantially parallel to one another. A defined distance between the first plate 5 and the second plate 6 is set by a spacer 10. For example, the defined distance is between 1 mm and 100 μm.

The sensor unit 11 has a sensor component 12 which forms at least a sub-region of the first plate 5 and/or the second plate 6. In the example in FIG. 2, the first plate 5 and the second plate 6 consist completely of the sensor component 12. The sensor component 12 is, for example, at least one crystal body with at least one vacancy or at least one gas cell. The crystal body is optionally a diamond with at least one nitrogen vacancy center or with at least one silicon vacancy center, silicon carbide with at least one silicon vacancy center or, hexagonal boron nitride with at least one vacancy color center. The gas cell contains, for example, a gaseous alkali metal in a cell.

The sensor unit 11 can optionally also be an excitation unit 14 for the optical excitation of the sensor component 12 and a detection unit 15 for detecting the fluorescence signal of the sensor component 12 that is influenced by the nuclear spin resonances of the sample 4 and is arranged, for example, adjacent to the first plate 5 and the second plate 6. In this way, an optical beam path through the sample 4 is possible. An analysis unit 13 is also arranged for ascertaining the at least one chemical and/or physical property of the sample 4 using the detected variable. To display and/or transmit the at least one chemical and/or physical variable to an external unit, a transmitting unit and/or a display unit can optionally also be present.

For the induction of a preferred polarization of the nuclear spins of the sample 4, an optional inductor 17 is provided which is shown as a magnetic field device 18 in the example in FIG. 2. The magnetic field device 18 generates a homogeneous magnetic field at least in the region of the sample 4 and in the region of the sensor component and is designed in two parts in FIG. 2. This results in a magnetic yoke in measuring position 8.

FIG. 3 shows a second embodiment of the device 3 according to the invention, wherein the mechanism 7 has set a receiving position 9 in this example by unfolding the device 3 between the first plate 5 and the second plate 6. The mechanism 7 is, for example, a folding mechanism and comprises a hinge mechanism. In the receiving position 9, the liquid or pasty sample 4 can be applied in the form of a drop onto the first plate 5 or the second plate 6 in a simple manner. The sample has, for example, a volume of less than 100 μl, in particular of less than 10 μl.

The detection unit 15 is optionally designed in such a way that the detection unit 15 substantially detects only the fluorescence signal of the sensor component 12. For example, this is achieved with an absorption filter 16 which is arranged between the detection unit 15 and the second plate 6. In addition, a microwave source 19 is arranged in the region of the sensor component 12 for excitation of the sensor component 12. By way of example, the sensor component 12 is shown as a coating on one surface each of the first plate 5 and the second plate 6, which each face the sample 4.

FIG. 4 shows a fourth embodiment of the device 3 according to the invention which is designed in two parts in this example. In contrast to FIGS. 2-3, a top view is shown rather than a side view. In this example, the magnetic field device 18 is designed as a yoke which surrounds the first plate 5 in the receiving position 9. If the second plate 6 is clipped into or attached to the mechanism 7, for example, the second plate 6 is also surrounded in the measuring position 8 by the magnetic field device 18.

### LIST OF REFERENCE SIGNS

1 Excitation light
2 Fluorescent light
3 Device
4 Sample
5 First plate
6 Second plate
7 Mechanism
8 Measuring position
9 Receiving position
10 Spacer
11 Sensor unit
12 Sensor component
13 Analysis unit
14 Excitation unit
15 Detection unit
16 Absorption filter
17 Inductor
18 Magnetic field device
19 Microwave source

1-15. (canceled)

16. A device for analyzing a liquid or pasty sample, which is provided in the form of drops, using nuclear spin resonances of the sample, the device comprising:
a first panel and a second panel;
a mechanism operable to enable setting a measuring position and a recording position of the device such that the sample can be inserted between the first plate and the second plate in the recording position, wherein the first plate and the second plate are arranged substantially parallel to each other in the measuring position, and wherein a spacer sets a defined distance between the first plate and the second plate;
a sensor unit including a sensor component, which forms at least one sub-region of the first plate and/or the second plate and at least partially contacts the sample, wherein the sensor unit is configured to detect a variable that is influenced by the nuclear magnetic resonances of the sample; and
an analysis unit configured to determine at least one chemical and/or physical property of the sample using the detected variable.

17. The device according to claim 16, wherein the sensor component comprises at least one crystal body having at least one vacancy or at least one gas cell.

18. The device according to claim 17, wherein the at least one crystal body is a diamond having at least one nitrogen vacancy center or having at least one silicon vacancy center, silicon carbide having at least one silicon vacancy center, or hexagonal boron nitride having at least one vacancy color center.

19. The device according to claim 17, wherein the gas cell is a cell which includes at least one gaseous alkali metal.

20. The device according to claim 16, wherein the sensor unit includes an excitation unit operable for the optical excitation of the sensor component and a detection unit operable for the detection of a fluorescence signal from the sensor component, which fluorescence signal is influenced by the nuclear spin resonances of the sample.

21. The device according to claim 20, wherein the excitation unit and/or the detection unit are disposed adjacent the first plate and/or the second plate such that an optical beam path through the sample can be generated.

22. The device according to claim 21, wherein the detection unit is configured such that the detection unit detects the fluorescence signal from the sensor component and does not detect the excitation light of the excitation unit.

23. The device according to claim 22, wherein the detection unit includes an absorption filter, wherein the absorption filter is arranged between the detection unit and the first plate or the second panel.

24. The device according to claim 16, wherein the mechanism is a folding mechanism.

25. The device according to claim 24, wherein the folding mechanism comprises a hinge mechanism.

26. The device according to claim 16, further comprising an inductor configured to induce a preferred polarization of the nuclear spins of the sample.

27. The device according to claim 26, wherein the inductor is a magnetic field device configured to generate a magnetic field at least in a region of the sample.

28. The device according to claim 27, wherein the magnetic field device is arranged adjacent the excitation unit and/or detection unit such that a homogeneous magnetic field can be generated in the region of the sample,
wherein the magnetic field device is configured as a yoke or in two parts.

29. The device according to claim 16, wherein the device is configured to operate on a sample having a volume of less than 100 microliters (μl).

30. The device according to claim 16, wherein the device is configured to operate on a sample having a volume of less than 10 μl.

31. The device according to claim 16, wherein the defined distance between the first plate and the second plate is between 1 millimeter (mm) and 100 μm.

32. The device according to claim 16, wherein the sensor unit includes a microwave source configured for excitation of the sensor component.

33. The device according to claim 16, wherein the sensor component is a coating on a surface of the first plate facing the sample and/or the second plate.
